(19) United States
(12) Patent Application Publication
(10) Pub. No.: US 2023/0246079 A1
(43) Pub. Date: Aug. 3, 2023

(54) SEMICONDUCTOR DEVICE

(71) Applicant: KABUSHIKI KAISHA TOSHIBA, Tokyo (JP)

(72) Inventors: Yosuke KAJIWARA, Yokohama (JP); Masahiko KURAGUCHI, Yokohama (JP); Aya SHINDOME, Yokohama (JP); Hiroshi ONO, Tokyo (JP)

(73) Assignee: KABUSHIKI KAISHA TOSHIBA, Tokyo (JP)

(21) Appl. No.: 17/820,996

(22) Filed: Aug. 19, 2022

(30) Foreign Application Priority Data
Feb. 1, 2022 (JP) 2022-013920

(51) Int. Cl. H01L 29/20; H01L 29/778; H01L 29/423; H01L 23/482; H01L 29/205

(52) U.S. Cl. CPC H01L 29/2003; H01L 29/7786; H01L 29/4238; H01L 23/4824; H01L 29/42316; H01L 29/205

(57) ABSTRACT

According to one embodiment, a semiconductor device includes a semiconductor member, an electrode portion, a pad portion, and first and second conductive members. The semiconductor member includes a first semiconductor layer and a second semiconductor layer. The electrode portion includes a source electrode, a gate electrode including a first gate portion, and a drain electrode. The first gate portion is between the source electrode and the drain electrode. The pad portion includes a drain pad. The first conductive member includes a first conductive portion. The drain pad is between the electrode portion and the first conductive portion. The second conductive member includes at least one of first to third conductive regions. The first conductive portion is between the drain pad and the first conductive region. The electrode portion is between the second conductive region and the third conductive region.

### CROSS-REFERENCE TO RELATED APPLICATIONS

This application is based upon and claims the benefit of priority from Japanese Patent Application No. 2022-013920, filed on Feb. 1, 2022; the entire contents of which are incorporated herein by reference.

### FIELD

Embodiments of the invention generally relate to a semiconductor device.

### BACKGROUND

For example, in a semiconductor device such as a transistor, stable characteristics are desired.

### BRIEF DESCRIPTION OF THE DRAWINGS

FIG. 1 is a schematic plan view illustrating a semiconductor device according to a first embodiment;

FIG. 2 is a schematic plan view illustrating the semiconductor device according to the first embodiment;

FIG. 3 is a schematic plan view illustrating the semiconductor device according to the first embodiment;

FIG. 4 is a schematic plan view illustrating the semiconductor device according to the first embodiment;

FIG. 5 is a schematic cross-sectional view illustrating the semiconductor device according to the first embodiment;

FIG. 6 is a schematic cross-sectional view illustrating the semiconductor device according to the first embodiment;

FIG. 7 is a schematic cross-sectional view illustrating the semiconductor device according to the first embodiment;

FIG. 8 is a schematic cross-sectional view illustrating the semiconductor device according to the first embodiment;

FIG. 9 is a schematic cross-sectional view illustrating the semiconductor device according to the first embodiment;

FIG. 10 is a schematic plan view illustrating the semiconductor device according to the first embodiment;

FIG. 11 is a schematic plan view illustrating the semiconductor device according to the first embodiment;

FIG. 12 is a schematic cross-sectional view illustrating the semiconductor device according to the first embodiment;

FIG. 13 is a schematic cross-sectional view illustrating the semiconductor device according to the first embodiment;

FIG. 14 is a schematic plan view illustrating the semiconductor device according to the first embodiment;

FIG. 15 is a schematic plan view illustrating the semiconductor device according to a second embodiment;

FIG. 16 is a schematic plan view illustrating the semiconductor device according to the second embodiment;

FIGS. 17A and 17B are schematic plan views illustrating a method for manufacturing a semiconductor device according to an embodiment;

FIGS. 18A and 18B are schematic plan views illustrating the method for manufacturing the semiconductor device according to the embodiment; and

FIGS. 19A and 19B are schematic plan views illustrating the method for manufacturing the semiconductor device according to the embodiment.

### DETAILED DESCRIPTION

According to one embodiment, a semiconductor device includes a semiconductor member, an electrode portion, a pad portion, a first conductive member, and a second conductive member. The semiconductor member includes a first semiconductor layer including Alₓ₁Ga₁₋ₓ₁N (0≤x1<1) and a second semiconductor layer including Alₓ₂Ga₁₋ₓ₂N (0<x2≤1, x1<x2). The electrode portion includes a source electrode extending along a first direction, a gate electrode including a first gate portion extending along the first direction, and a drain electrode extending along the first direction. The first gate portion is located between the source electrode and the drain electrode in a second direction crossing the first direction. The pad portion includes a drain pad electrically connected to the drain electrode. The first conductive member is electrically connected to the gate electrode. The first conductive member includes a first conductive portion. A position of the drain pad in the first direction is between a position of the electrode portion in the first direction and a position of the first conductive portion in the first direction. The second conductive member is electrically connected to the source electrode. The second conductive member includes at least one of a first conductive region, a second conductive region, or a third conductive region. A position of the first conductive portion in the first direction is between the position of the drain pad in the first direction and the position of the first conductive region in the first direction. A position of the electrode portion in the second direction is between a position of the second conductive region in the second direction and a position of the third conductive region in the second direction.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously in an antecedent drawing are marked with like reference numerals, and a detailed description is omitted as appropriate.

### FIRST EMBODIMENT

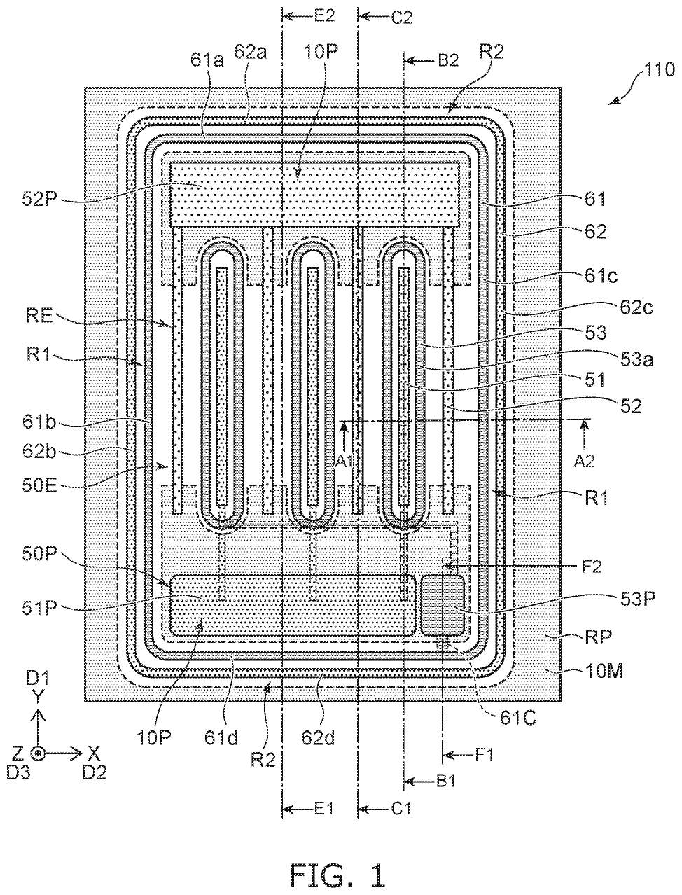

FIGS. 1 to 4 are schematic plan views illustrating a semiconductor device according to a first embodiment. In FIGS. 1 to 4, some members are taken out and illustrated in order to make the figure easier to see.

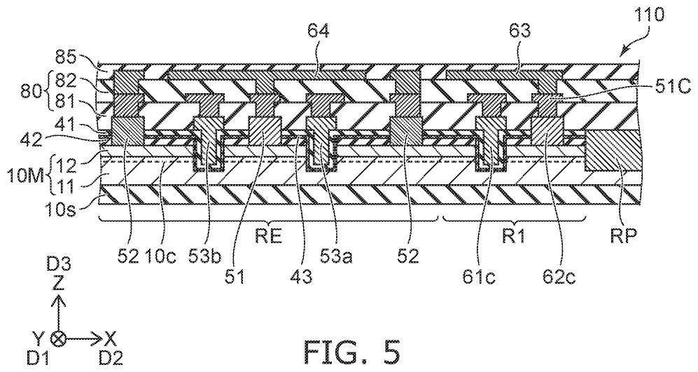

FIGS. 5 to 9 are schematic cross-sectional views illustrating the semiconductor device according to the first embodiment.

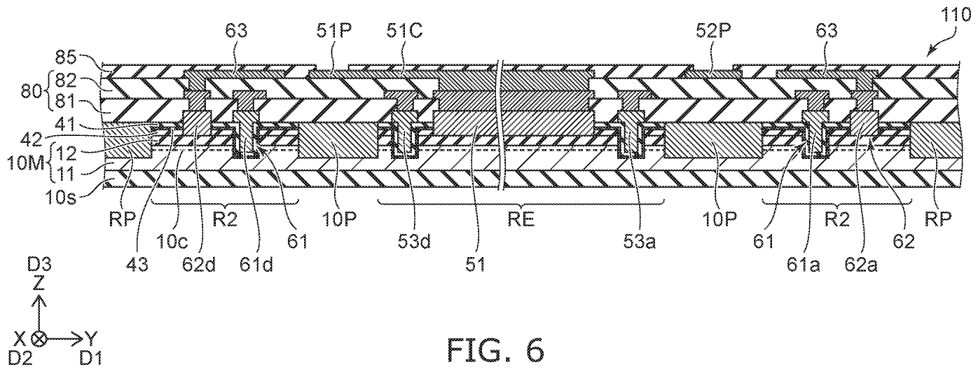

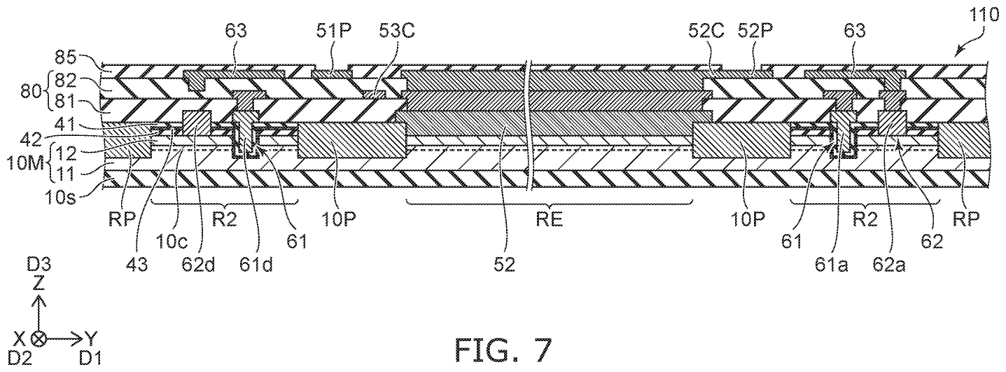

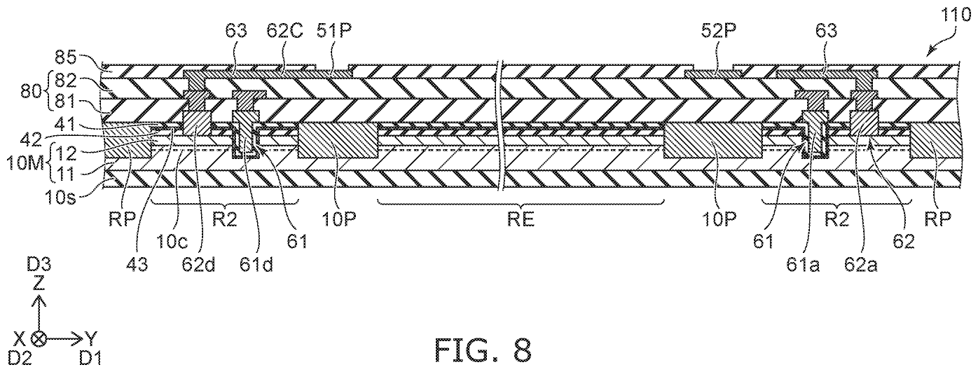

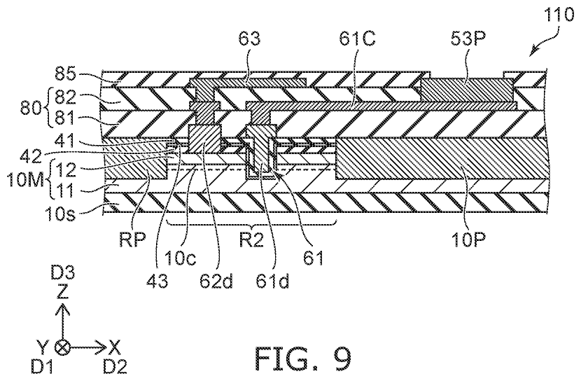

FIG. 5 is a sectional view taken along the line A1-A2 of FIG. 1. FIG. 6 is a sectional view taken along the line B1-B2 of FIG. 1. FIG. 7 is a cross-sectional view taken along the line C1-C2 of FIG. 1. FIG. 8 is a cross-sectional view taken along the line E1-E2 of FIG. 1. FIG. 9 is a cross-sectional view taken along the line F1-F2 of FIG. 1.

As shown in FIG. 1 and FIGS. 5 to 9, a semiconductor device 110 according to the embodiment includes a semiconductor member 10M, an electrode portion 50E, a pad portion 50P, a first conductive member 61, and a second conductive member 62.

As shown in FIGS. 5 to 9, the semiconductor member 10M includes a first semiconductor layer 11 and a second semiconductor layer 12. The first semiconductor layer 11 includes Alₓ₁Ga₁₋ₓ₁N (0≤x1<1) ). The composition ratio x1 is, for example, not less than 0 and less than 0.1. The first semiconductor layer 11 is, for example, a GaN layer.

The second semiconductor layer 12 includes Alₓ₂Ga₁₋ₓ₂N (0<x2≤1, x1<x2). The composition ratio x2 is, for example, not less than 0.1 and not more than 0.35. The second semiconductor layer 12 is, for example, an AlGaN layer.

The semiconductor device 110 may further include a base body 10s. The first semiconductor layer 11 is located between the base body 10s and the second semiconductor layer 12. The base body 10s may include, for example, a silicon substrate or a SiC substrate.

The first semiconductor layer 11 is provided above the base body 10s. The second semiconductor layer 12 is provided above the first semiconductor layer 11. The electrode portion 50E, the pad portion 50P, the first conductive member 61, and the second conductive member 62 are provided above the semiconductor member 10M. For example, a superlattice layer may be provided between the base body 10s and the first semiconductor layer 11. The superlattice layer has, for example, a stacked structure including an AlGaN layer and a GaN layer. For example, a nitride layer including carbon (for example, a GaN layer) may be provided between the base body 10s and the first semiconductor layer 11. A concentration of carbon in the nitride layer including carbon is higher than a concentration of carbon in the first semiconductor layer 11. For example, an AlGaN back barrier layer may be provided between the base body 10s and the first semiconductor layer 11. For example, at least one of the superlattice layer, the nitride layer including carbon, and the AlGaN back barrier layer may be provided.

As shown in FIG. 1, the electrode portion 50E includes a source electrode 51, a gate electrode 53, and a drain electrode 52. The source electrode 51 extends along a first direction D1. The first direction D1 is a Y-axis direction. One direction perpendicular to the Y-axis direction is defined as an X-axis direction. The direction perpendicular to the Y-axis direction and the X-axis direction is defined as a Z-axis direction.

The gate electrode 53 includes a first gate portion 53a. The first gate portion 53a extends along the first direction D1. The drain electrode 52 extends along the first direction D1. The first gate portion 53a is located between the source electrode 51 and the drain electrode 52 in a second direction D2. The second direction D2 crosses the first direction D1. The second direction D2 is, for example, the X-axis direction.

The pad portion 50P includes a drain pad 52P. The drain pad 52P is electrically connected to the drain electrode 52. In this example, the pad portion 50P includes a source pad 51P and a gate pad 53P. The source pad 51P is electrically connected to the source electrode 51. The gate pad 53P is electrically connected to the gate electrode 53.

The first conductive member 61 is electrically connected to the gate electrode 53. The first conductive member 61 includes a first conductive portion 61a. A position of the drain pad 52P in the first direction D1 is between a position of the electrode portion 50E in the first direction D1 and a position of the first conductive portion 61a in the first direction D1.

The second conductive member 62 is electrically connected to the source electrode 51. The second conductive member 62 includes at least one of a first conductive region 62a, a second conductive region 62b, or a third conductive region 62c. A position of the first conductive portion 61a in the first direction D1 is between a position of the drain pad 52P in the first direction D1 and a position of the first conductive region 62a in the first direction D1. For example, in a plan view, the first conductive portion 61a is between the drain pad 52P and the first conductive region 62a.

A position of the electrode portion 50E in the second direction D2 is between a position of the second conductive region 62b in the second direction D2 and a position of the third conductive region 62c in the second direction D2. For example, in a plan view, the source electrode 51, the gate electrode 53, and the drain electrode 52 are located between the second conductive region 62b and the third conductive region 62c in the second direction D2.

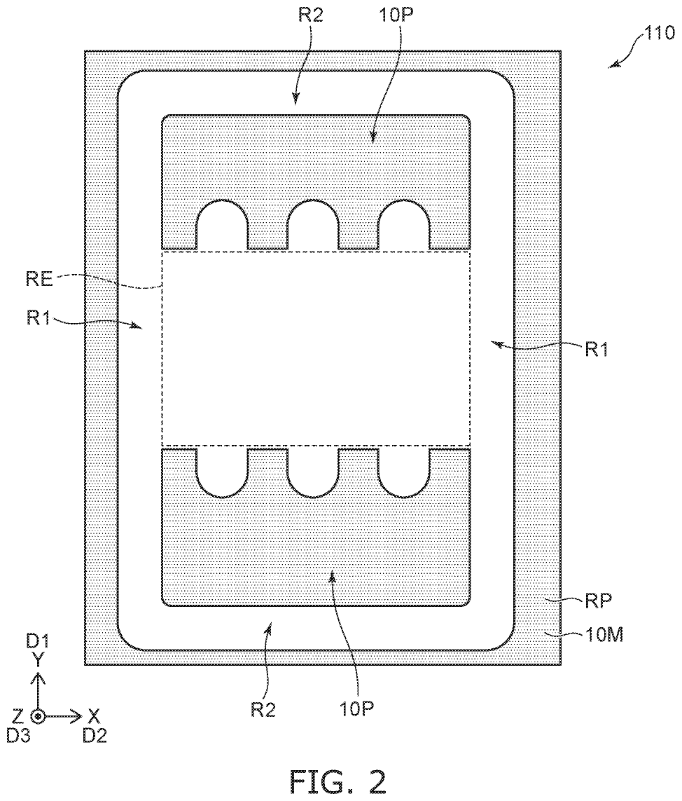

FIG. 2 illustrates the semiconductor member 10M. As shown in FIG. 2, the semiconductor member 10M includes an element region RE, a pad portion region 10P, a peripheral region RP, a first intermediate region R1 and a second intermediate region R2. The peripheral region RP is located around the element region RE and the pad portion region 10P in a plane (for example, an X-Y plane) including the first direction D1 and the second direction D2. The first intermediate region R1 is between the element region RE and the peripheral region RP. The second intermediate region R2 is between the pad portion region 10P and the peripheral region RP.

As shown in FIGS. 1 and 2, the electrode portion 50E is provided in the element region RE. The pad portion 50P is provided in the pad portion region 10P. In this example, the pad portion 50P includes a drain pad 52P, a source pad 51P, and a gate pad 53P. The drain pad 52P is provided in a part of the pad portion region 10P. The source pad 51P and the gate pad 53P are provided in another part of the pad portion region 10P.

At least a part of the first conductive member 61 and at least a part of the second conductive member 62 are provided in at least one of the first intermediate region R1 or the second intermediate region R2.

As shown in FIG. 1, in this example, the first conductive member 61 further includes a second conductive portion 61b and a third conductive portion 61c. A position of the second conductive portion 61b in the second direction D2 is between the position of the second conductive region 62b in the second direction D2 and the position of the electrode portion 50E in the second direction D2. A position of the third conductive portion 61c in the second direction D2 is between the position of the electrode portion 50E in the second direction D2 and the position of the third conductive region 62c in the second direction D2.

For example, the second conductive portion 61b and the third conductive portion 61c may be continuous with the first conductive portion 61a. For example, the second conductive region 62b and the third conductive region 62c may be continuous with the first conductive region 62a.

For example, there is a reference example in which the first conductive member 61 and the second conductive member 62 are not provided at the end of the electrode portion 50E in the X-axis direction (the end of the element region RE in the X-axis direction). In this reference example, a conductive member (the first conductive member 61, the second conductive member 62, etc.) having a low voltage is not provided in the path between the drain electrode 52 to which a high voltage is applied and the peripheral region RP. Therefore, a high electric field is generated in the region between the end of the electrode portion 50E in the X-axis direction and the peripheral region RP. This may result in leakage current. In particular, in a high temperature and high humidity operation test (THB: thermal humidity bias test) or the like, the leakage current becomes large. This may result in unstable operation. For example, the semiconductor device may be destroyed.

On the other hand, in the embodiment, for example, the first conductive member 61 (for example, the second conductive portion 61b and the third conductive portion 61c) is provided between the end of the electrode portion 50E in the X-axis direction and the peripheral region RP. Further, the second conductive member 62 (for example, a second conductive region 62b and a third conductive region 62c) is provided between the first conductive member 61 and the peripheral region RP. As a result, the electric field is low at the end of the element region RE in the X-axis direction. For example, the electric field strength is substantially zero. In the embodiment, the leakage current can be suppressed. Destruction of semiconductor devices in high-temperature and high-humidity operation tests is unlikely to occur.

In the embodiment, for example, the first conductive member 61 (for example, the first conductive portion 61a) is provided between the drain pad 52P and the peripheral region RP. For example, the second conductive member 62 (for example, the first conductive region 62a) is provided between the first conductive member 61 and the peripheral region RP. As a result, the electric field is low in the region between the drain pad 52P and the peripheral region RP. In the embodiment, the leakage current can be suppressed. In the embodiment, a semiconductor device capable of stabilizing the characteristics can be provided.

As already described, the pad portion 50P may further include the source pad 51P. The source pad 51P is electrically connected to the source electrode 51. For example, the position of the electrode portion 50E (source electrode 51, gate electrode 53, and drain electrode 52) in the first direction D1 is between a position of the source pad 51P in the first direction D1 and the position of the drain pad 52P in the first direction D1.

As already described, the pad portion 50P may further include the gate pad 53P. The gate pad 53P is electrically connected to the gate electrode 53. For example, a position of the electrode portion 50E in the first direction D1 is between a position of the gate pad 53P in the first direction D1 and the position of the drain pad 52P in the first direction D1.

As shown in FIG. 1, the first conductive member 61 may further include a fourth conductive portion 61d. The second conductive member 62 may further include a fourth conductive region 62d. The position of the electrode portion 50E in the first direction D1 is between a position of the fourth conductive region 62d in the first direction D1 and the position of the drain pad 52P in the first direction D1. A position of the fourth conductive portion 61d in the first direction D1 is between the position of the fourth conductive region 62d in the first direction D1 and the position of the electrode portion 50E in the first direction D1.

For example, the fourth conductive portion 61d is continuous with the first conductive portion 61a. The first to fourth conductive portions 61a to 61d may be continuous with each other. The fourth conductive region 62d is continuous with the second conductive region 62b and the third conductive region 62c. The first to fourth conductive regions 62a to 62d may be continuous with each other.

For example, in a plan view, the electrode portion 50E may be surrounded by the first conductive member 61. In a plan view, the first conductive member 61 may be surrounded by the second conductive member 62. For example, in a plan view, the pad portion 50P may be surrounded by the first conductive member 61. In a plan view, the peripheral region RP is provided around these conductive members. Leakage current is more suppressed.

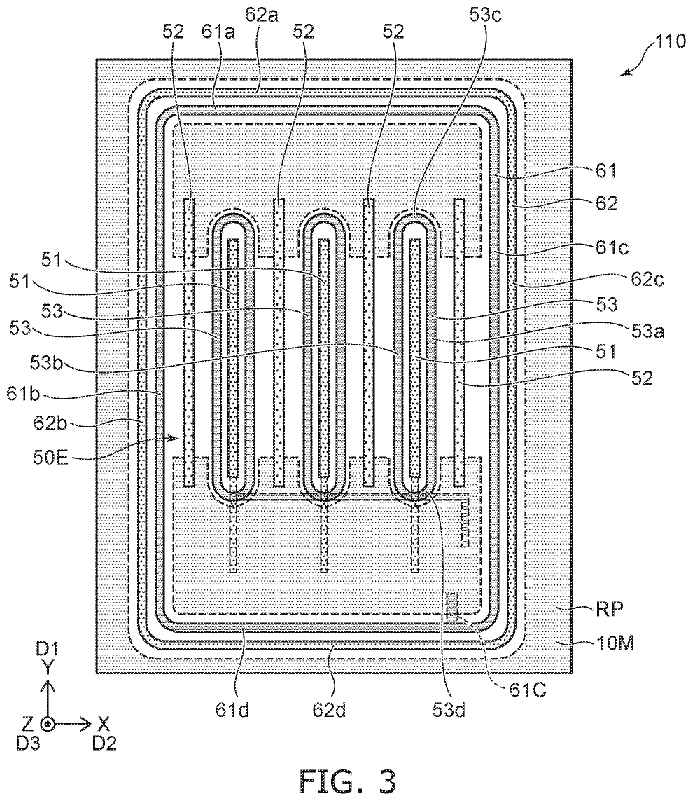

FIG. 3 illustrates the planar shapes of the source electrode 51, the gate electrode 53, the drain electrode 52, the first conductive member 61, and the second conductive member 62.

As shown in FIG. 3, in this example, the gate electrode 53 further includes a second gate portion 53b, a third gate portion 53c, and a fourth gate portion 53d. The second gate portion 53b extends along the first direction D1.

In the second direction D2, the source electrode 51 is located between the second gate portion 53b and the drain electrode 52. In the second direction D2, the source electrode 51 is between the second gate portion 53b and the first gate portion 53a. In the first direction D1, the source electrode 51 is located between the third gate portion 53c and the fourth gate portion 53d. For example, the source electrode 51 is located between the plurality of portions of the gate electrode 53 in the second direction D2 and the first direction D1. For example, there is the gate electrode 53 in the path between the source electrode 51 and the drain electrode 52. As a result, the leakage current is suppressed even in the element region RE. The characteristics can be made more stable.

For example, the first gate portion 53a, the second gate portion 53b, the third gate portion 53c, and the fourth gate portion 53d may be continuous with each other. For example, the source electrode 51 may be surrounded by the first gate portion 53a, the second gate portion 53b, the third gate portion 53c, and the fourth gate portion 53d in the X-Y plane (a plane including the first direction D1 and the second direction D2). More stable characteristics can be obtained.

As shown in FIG. 3, a plurality of source electrodes 51, a plurality of gate electrodes 53, and a plurality of drain electrodes 52 may be provided.

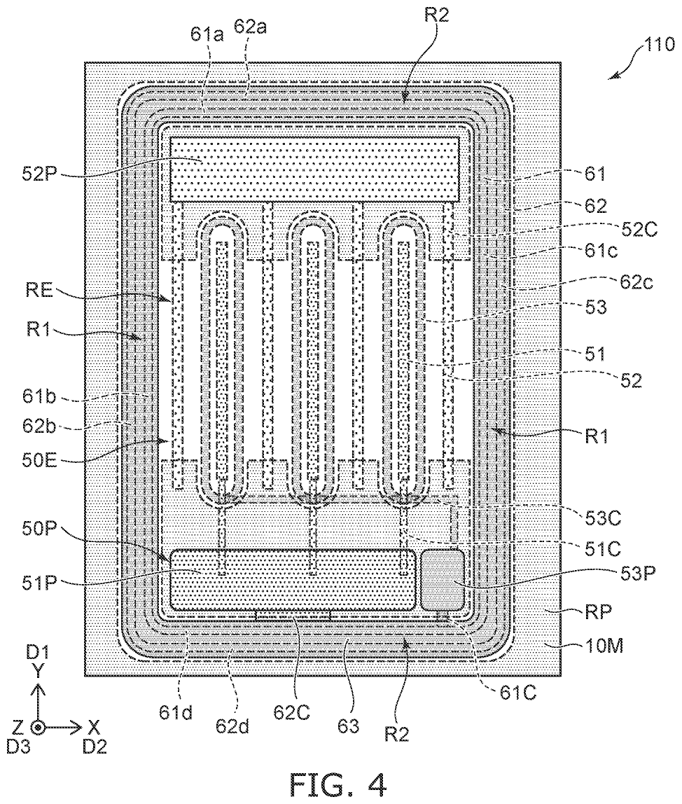

As shown in FIGS. 4 and 6, the source electrode 51 may be electrically connected to the source pad 51P by a source connecting portion 51C.

As shown in FIG. 4, the gate electrode 53 may be electrically connected to the gate pad 53P by a gate connecting portion 53C.

As shown in FIGS. 4 and 7, the drain electrode 52 may be electrically connected to the drain pad 52P by a drain connecting portion 52C.

As shown in FIGS. 4 to 9, the semiconductor device 110 may further include a third conductive member 63. The third conductive member 63 is electrically connected to the second conductive member 62. At least a part of the first conductive member 61 is between the semiconductor member 10M and the third conductive member 63 in a third direction D3. The third direction D3 crosses a plane (the X-Y plane) including the first direction D1 and the second direction D2. The third direction D3 is, for example, a Z-axis direction. The third conductive member 63 functions as, for example, a field plate. For example, the local concentration of the electric field is suppressed. It is easy to obtain more stable operation.

As shown in FIG. 5, the third conductive portion 61c is located between the semiconductor member 10M and the third conductive member 63 in the third direction D3. Similarly, the second conductive portion 61b may be located between the semiconductor member 10M and the third conductive member 63 in the third direction D3.

As shown in FIG. 6, the first conductive portion 61a is located between the semiconductor member 10M and the third conductive member 63 in the third direction D3. The fourth conductive portion 61d is located between the semiconductor member 10M and the third conductive member 63 in the third direction D3.

As shown in FIGS. 4 and 8, the semiconductor device 110 may include a second conductive member connecting portion 62C. The second conductive member connecting portion 62C electrically connects the second conductive member 62 to the source pad 51P. At least a part of the first conductive member 61 is located between the semiconductor member 10M and the third conductive member 63 in the third direction D3. At least a part of the second conductive member connecting portion 62C is located between the third conductive member 63 and the source pad 51P in the first direction D1. For example, at least a part of the second conductive member connecting portion 62C may be in the same layer as the third conductive member 63 and the source pad 51P.

As shown in FIGS. 4 and 9, the semiconductor device 110 may include a first conductive member connecting portion 61C. The first conductive member connecting portion 61C electrically connects the first conductive member 61 to the gate pad 53P. As shown in FIG. 9, a position of at least a part of the first conductive member connecting portion 61C in the third direction D3 is between a position of the first conductive member 61 in the third direction D3 and the position of the gate pad 53P in the third direction D3.

As shown in FIG. 6, the position of the first conductive member 61 (the first conductive portion 61a, the fourth conductive portion 61d, etc.) in the third direction D3 is the same as a position of the gate electrode 53 (first gate portion 53a and fourth gate portion 53d, etc.) in the third direction D3. A position of at least a part of the of the first conductive member connecting portion 61C in the third direction D3 is between the position of the gate electrode 53 in the third direction D3 and the position of the gate pad 53P in the third direction D3.

As shown in FIG. 5, the semiconductor device 110 may include a fourth conductive member 64. The fourth conductive member 64 is electrically connected to the source electrode 51. At least a part of the gate electrode 53 (the first to fourth gate portions 53a to 53d and the like) is located between the semiconductor member 10M and the fourth conductive member 64 in the third direction D3. The fourth conductive member 64 functions as, for example, a field plate. For example, the local concentration of the electric field is suppressed. It is easy to obtain more stable operation.

As shown in FIG. 5, in this example, the gate electrode 53 is provided between a plurality of regions of the second semiconductor layer 12 in the X-Y plane. A part of the gate electrode 53 may be provided between a plurality of regions of the first semiconductor layer 11 in the X-Y plane. For example, the first gate portion 53a is located between a part of the second semiconductor layer 12 and an other part of the second semiconductor layer 12 in the second direction D2. For example, the first gate portion 53a may be provided between a part of the first semiconductor layer 11 and an other part of the first semiconductor layer 11 in the second direction D2. The gate electrode 53 is, for example, a recess type gate electrode. With such a configuration, for example, a normally-off operation can be obtained. In embodiments, normally-on operation may be applied.

As shown in FIG. 5, the first semiconductor layer 11 includes a region facing the second semiconductor layer 12. A carrier region 10c is formed in this region. The carrier region 10c is, for example, a two-dimensional electron gas. The semiconductor device 110 is, for example, a HEMT (High Electron Mobility Transistor). Current flowing between the source electrode 51 and the drain electrode 52 is controlled by a potential of the gate electrode 53. The potential of the gate electrode 53 may be, for example, a potential based on the potential of the source electrode 51.

The semiconductor device 110 may include a first insulating member 41 and a second insulating member 42. At least a part of the first insulating member 41 is provided between the gate electrode 53 and the semiconductor member 10M. In the third direction D3, the second semiconductor layer 12 is located between the first semiconductor layer 11 and the second insulating member 42. The second insulating member 42 is located between the second semiconductor layer 12 and a part of the first insulating member 41 in the third direction D3. The second insulating member 42 is, for example, a protective film.

The first insulating member 41 includes at least one selected from the group consisting of oxygen and nitrogen and at least one selected from the group consisting of silicon and aluminum. In one example, the first insulating member 41 includes silicon oxide.

The second insulating member 42 includes at least one selected from the group consisting of silicon and aluminum and at least one selected from the group consisting of oxygen and nitrogen. The concentration of nitrogen in the first insulating member 41 is lower than the concentration of nitrogen in the second insulating member 42. In one example, the first insulating member 41 includes at least one of silicon nitride, aluminum nitride, aluminum oxide, or silicon oxide. The second insulating member 42 may be amorphous. For example, the leakage current is suppressed. It is easy to obtain more stable operation.

As shown in FIG. 5, the semiconductor device 110 may include a compound member 43. A part of the compound member 43 is provided between the first insulating member 41 and the semiconductor member 10M. A part of the compound member 43 may be provided between the second insulating member 42 and the first insulating member 41. The compound member 43 includes AlN or AlGaN. The composition ratio of Al in the compound member 43 is higher than the composition ratio of Al in the second semiconductor layer 12. By providing the compound member 43, higher carrier mobility can be obtained. Low on-resistance is obtained in semiconductor devices.

As shown in FIG. 5, the semiconductor device 110 may include an interlayer insulating portion 80. The interlayer insulating portion 80 includes, for example, an interlayer insulating film 81 and an interlayer insulating film 82.

As shown in FIG. 6, the semiconductor device 110 may include an insulating film 85. A part of the insulating film 85 may be provided on the third conductive member 63. The insulating film 85 may be provided on a part of the source pad 51P, a part of the drain pad 52P, and a part of the gate pad 53P. The insulating film 85 functions as, for example, a protective film.

As already described with respect to FIG. 2, the semiconductor member 10M may include the element region RE, the pad portion region 10P, the peripheral region RP, the first intermediate region R1 and the second intermediate region R2. The element region RE, the first intermediate region R1 and the second intermediate region R2 are, for example, “active regions”. The peripheral region RP and the pad portion region 10P are, for example, “inactive regions”. The peripheral region RP is, for example, an element separation region.

The crystallinity in the inactive region (the peripheral region RP and the pad portion region 10P) is lower than the crystallinity in the active region (the device region RE, the first intermediate region R1 and the second intermediate region R2). For example, in the inactive region, the crystallinity of the semiconductor member 10M is deteriorated.

In one example, the deterioration of the crystallinity of the semiconductor member 10M can be observed by PL (Photo Luminescence). In one example of PL evaluation, for example, when irradiated with a He-Cd laser having a peak wavelength of 325 nm, the excitation light spectrum in the inactive region is different from the excitation light spectrum in the active region.

For example, the light intensity of about 360 nm in the inactive region (the peripheral region RP and the pad region 10P) is lower than the light intensity of about 360 nm in the active region (the device region RE, the first intermediate region R1 and the second intermediate region R2). For example, the light intensity of about 530 nm in the inactive region (the peripheral region RP and the pad region 10P) is higher than the light intensity of about 530 nm in the active region (the device region RE, the first intermediate region R1 and the second intermediate region R2).

In one example, the crystallinity can be observed, for example, by TEM (Transmission Electron Microscope). In one example of TEM observation, in the TEM observation of the inactive region, disturbance is observed in the periodicity of the crystal lattice of the semiconductor member 10M.

In one example, for example, the inactive region (the peripheral region RP and the pad region 10P) includes a first element. The active region (the element region RE, the first intermediate region R1 and the second intermediate region R2) substantially does not include the first element. The first element includes at least one selected from the group consisting of Ar, P, B and N. The first element may be, for example, a heavy element. The first element is introduced, for example, by ion implantation.

For example, a concentration of the first element in the inactive region (the peripheral region RP and the pad region 10P) is higher than a concentration of the first element in the active region (the element region RE, the first intermediate region R1 and the second intermediate region R2).

For example, the first element is introduced into the inactive region. In the region where the first element is introduced, the crystallinity of the semiconductor member 10M deteriorates due to the collision damage of the first element. Due to the deterioration of crystallinity, the carrier region 10c (two-dimensional electron gas) is not substantially generated in the inactive region (the peripheral region RP and the pad portion region 10P). A carrier region 10c is generated in the active region (the device region RE, the first intermediate region R1 and the second intermediate region R2).

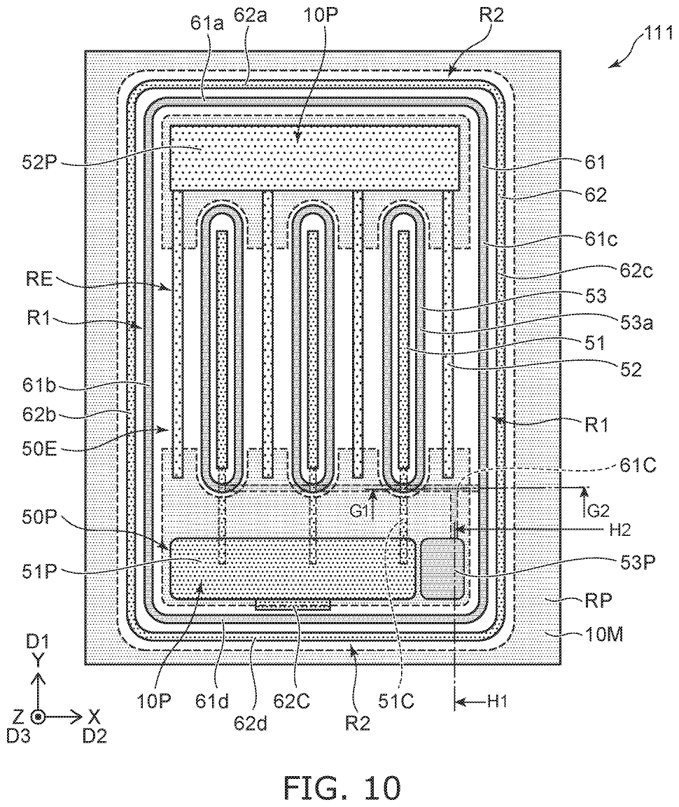

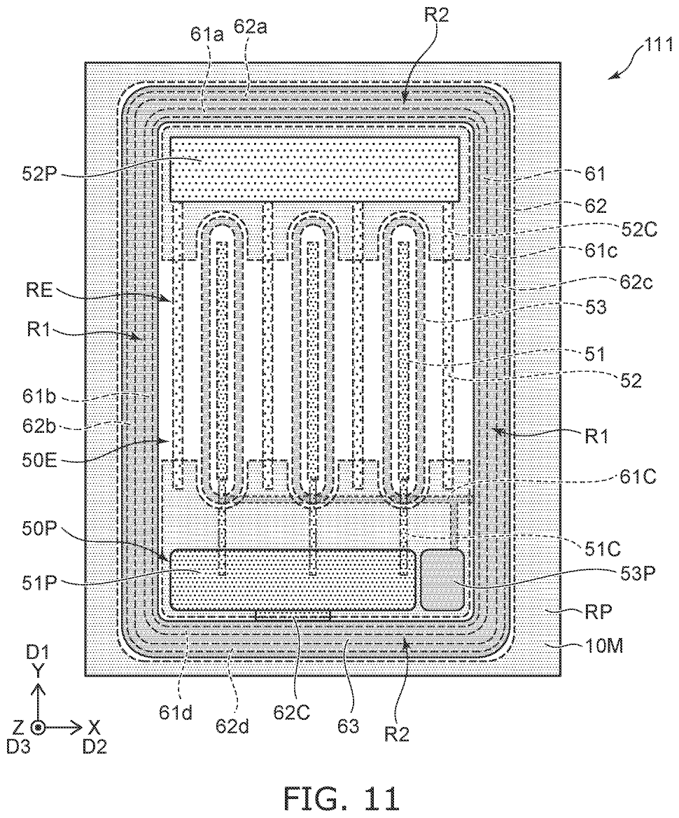

FIGS. 10 and 11 are schematic plan views illustrating the semiconductor device according to the first embodiment.

In FIGS. 10 and 11, some members are taken out and illustrated in order to make the figure easier to see.

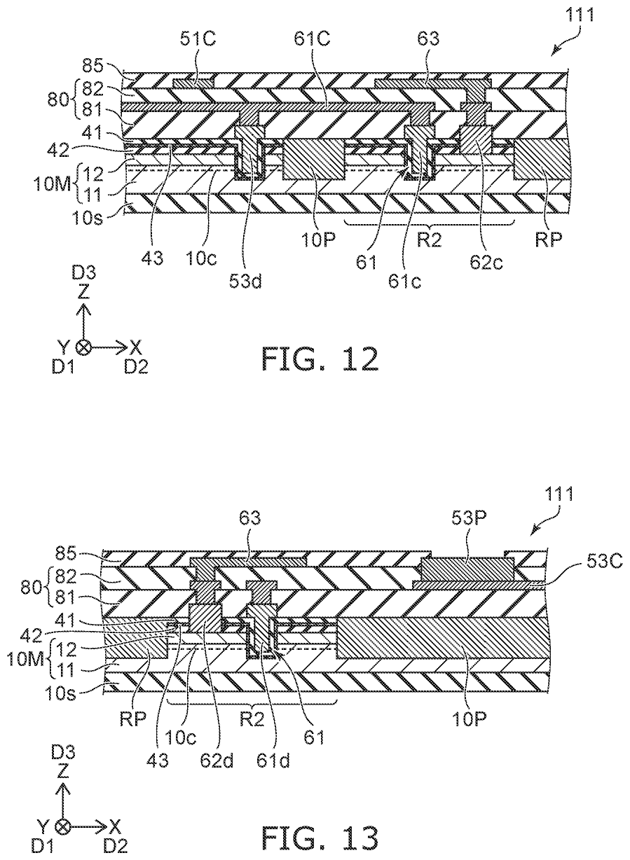

FIGS. 12 and 13 are schematic cross-sectional views illustrating the semiconductor device according to the first embodiment. FIG. 12 is a cross-sectional view taken along the line G1-G2 of FIG. 10. FIG. 13 is a sectional view taken along line H1-H2 of FIG. 10.

As shown in FIGS. 10 to 13, in a semiconductor device 111 according to the embodiment, the configuration of the first conductive member connecting portion 61C is different from the configuration of the first conductive member connecting portion 61C in the semiconductor device 110. Except for this, the configuration of the semiconductor device 111 may be the same as the configuration of the semiconductor device 110.

As shown in FIG. 12, in the semiconductor device 111, the position of the first conductive member 61 (for example, the third conductive portion 61c) in the third direction D3 is between the position of the semiconductor member 10M in the third direction D3 and the position of the first conductive member connecting portion 61C in the third direction D3. As shown in FIG. 13, the position of the gate connecting portion 53C in the third direction D3 is between the position of the first conductive member 61 (for example, the fourth conductive portion 61d) in the third direction D3 and the position of gate pad 53P in third direction D3. For example, the height of the gate connecting portion 53C with respect to the first semiconductor layer 11 may be substantially the same as the height of the third conductive portion 61c with respect to the first semiconductor layer 11.

Leakage current can also be suppressed in the semiconductor device 111. A semiconductor device capable of stabilizing characteristics can be provided.

In the semiconductor devices 110 and 111, when the length (width) of the second conductive member connecting portion 62C in the second direction D2 is short, the parasitic capacitance can be reduced. When the width is long, a stable connection can be made. The width can be varied in various ways.

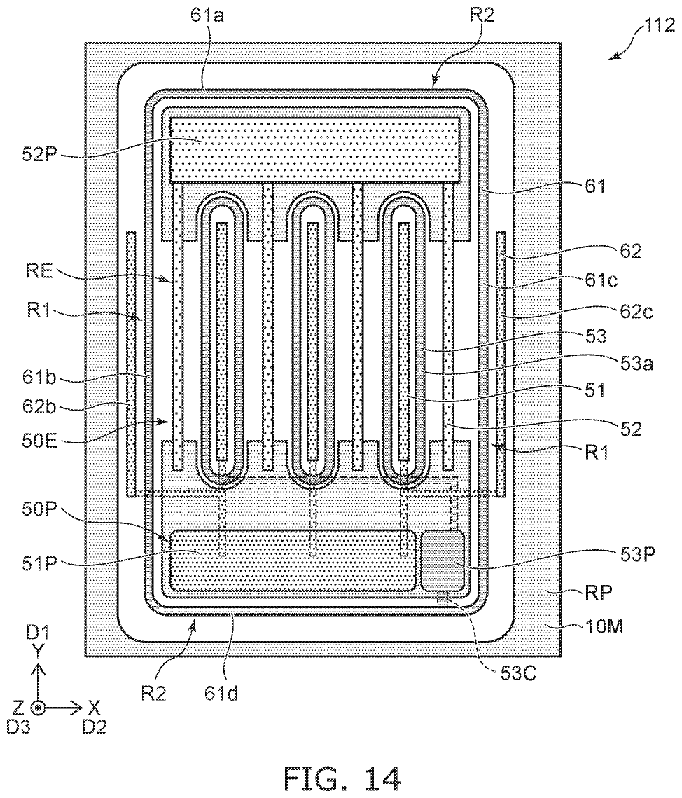

FIG. 14 is a schematic plan view illustrating the semiconductor device according to the first embodiment.

In FIG. 14, some members are taken out and illustrated in order to make the figure easier to see.

As shown in FIG. 14, in a semiconductor device 112 according to the embodiment, the second conductive member 62 includes the second conductive region 62b and the third conductive region 62c. The first conductive region 62a and the fourth conductive region 62d are omitted. Except for this, the configuration of the semiconductor device 112 may be the same as the configuration of the semiconductor device 110 or the semiconductor device 111.

Also in the semiconductor device 112, the first conductive member 61 (for example, the second conductive portion 61b and the third conductive portion 61c) is provided between the end of the electrode portion 50E in the X-axis direction and the peripheral region RP. Further, the second conductive member 62 (for example, the second conductive region 62b and the third conductive region 62c) is provided between the first conductive member 61 and the peripheral region RP. As a result, the electric field is low at the end of the first intermediate region R1 in the X-axis direction. Leakage current can also be suppressed in the semiconductor device 112. A semiconductor device capable of stabilizing characteristics can be provided. For example, in a high-temperature and high-humidity operation test, the semiconductor device is unlikely to be destroyed.

### SECOND EMBODIMENT

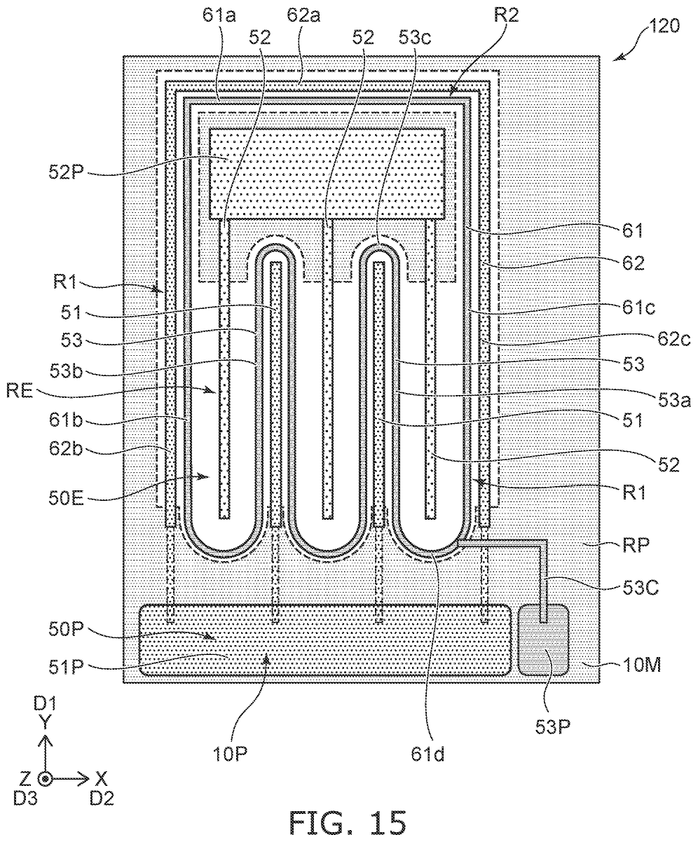

FIG. 15 is a schematic plan view illustrating a semiconductor device according to a second embodiment.

In FIG. 15, some members are taken out and illustrated in order to make the figure easier to see.

As shown in FIG. 15, a semiconductor device 120 according to the embodiment includes the semiconductor member 10M, the electrode portion 50E, the pad portion 50P, the first conductive member 61, and the second conductive member 62. In the semiconductor device 120, the configurations of the electrode portion 50E, the first conductive member 61, and the second conductive member 62 are different from those in the semiconductor device 110 to 112. Except for this, the configuration of the semiconductor device 120 may be the same as the configuration of the semiconductor devices 110 to 112.

For example, even in the semiconductor device 120, the semiconductor member 10M includes the first semiconductor layer 11 and the second semiconductor layer 12. Also in the semiconductor device 120, the electrode portion 50E includes the source electrode 51, the gate electrode 53, and the drain electrode 52. The source electrode 51 and the drain electrode 52 extend along the first direction D1.

The gate electrode 53 includes the first gate portion 53a, the second gate portion 53b, and the third gate portion 53c. The first gate portion 53a and the second gate portion 53b extend along the first direction D1. In the second direction D2 crossing the first direction D1, the first gate portion 53a is located between the source electrode 51 and the drain electrode 52. The source electrode 51 is located between the second gate portion 53b and the drain electrode 52. In the second direction D2, the source electrode 51 is located between the second gate portion 53b and the first gate portion 53a.

The pad portion 50P includes the drain pad 52P. The drain pad 52P is electrically connected to the drain electrode 52.

The first conductive member 61 is electrically connected to the gate electrode 53. In the semiconductor device 120, the first conductive member 61 includes the first conductive portion 61a, the second conductive portion 61b, and the third conductive portion 61c. The position of the drain pad 52P in the first direction D1 is between the position of the electrode portion 50E in the first direction D1 and the position of the first conductive portion 61a in the first direction D1.

The second conductive member 62 is electrically connected to the source electrode 51. In the semiconductor device 120, the second conductive member 62 includes the first conductive region 62a, the second conductive region 62b, and the third conductive region 62c. The position of the first conductive portion 61a in the first direction D1 is between the position of the drain pad 52P in the first direction D1 and the position of the first conductive region 62a in the first direction D1. The position of the electrode portion 50E in the second direction D2 is between the position of the second conductive region 62b in the second direction D2 and the position of the third conductive region 62c in the second direction D2. For example, the second conductive region 62b and the third conductive region 62c may be continuous with the first conductive region 62a.

The position of the second conductive portion 61b in the second direction D2 is between the position of the second conductive region 62b in the second direction D2 and the position of the electrode portion 50E in the second direction D2. The position of the third conductive portion 61c in the second direction D2 is between the position of the electrode portion 50E in the second direction D2 and the position of the third conductive region 62c in the second direction D2. For example, the second conductive portion 61b and the third conductive portion 61c may be continuous with the first conductive portion 61a.

The second conductive portion 61b is continuous with the second gate portion 53b. The third conductive portion 61c is continuous with the first gate portion 53a. The position of the third gate portion 53c in the first direction D1 is between the position of the source electrode 51 in the first direction D1 and the position of the drain pad 52P in the first direction D1.

In the semiconductor device 120, at least one of the gate electrode 53 or the first conductive member 61 is provided between the source electrode 51 and the drain electrode 52. A first conductive member 61 is provided between the drain electrode 52 and the second conductive member 62. The first conductive member 61 (the first conductive portion 61a) is provided between the drain pad 52P and the second conductive member 62 (the first conductive region 62a). The electric field can be lowered. For example, the leakage current can be suppressed. Also in the second embodiment, the semiconductor device capable of stabilizing the characteristics is provided.

In this example, the first conductive member 61 further includes the fourth conductive portion 61d. The position of the drain electrode 52 in the first direction D1 is between the position of the fourth conductive portion 61d in the first direction D1 and the position of the drain pad 52P in the first direction D1. For example, the fourth conductive portion 61d may be continuous with the second conductive portion 61b and the third conductive portion 61c.

For example, the drain electrode 52 may be surrounded by at least one of the gate electrode 53 or the first conductive member 61 in the X-Y plane. The X-Y plane is a plane including the first direction D1 and the second direction D2. For example, the source electrode 51 is outside a region surrounded by the at least one of the gate electrode 53 or the first conductive member 61. For example, at least one of the gate electrode 53 or the first conductive member 61 is provided in the path between the source electrode 51 and the drain electrode 52. For example, at least a part of the first conductive members 61 is provided in the path between the drain electrode 52 and the second conductive member 62. Leakage current is suppressed.

The pad portion 50P may include the source pad 51P. The source pad 51P is electrically connected to the source electrode 51. The position of the fourth conductive portion 61d in the first direction D1 is between the position of the source pad 51P in the first direction D1 and the position of the drain electrode 52 in the first direction D1.

The pad portion 50P may include the gate pad 53P. The gate pad 53P is electrically connected to the gate electrode 53. For example, the position of the fourth conductive portion 61d in the first direction D1 is between the position of the gate pad 53P in the first direction D1 and the position of the drain electrode 52 in the first direction D1.

Also in the semiconductor device 120, the semiconductor member 10M includes the peripheral region RP, the pad portion region 10P, the peripheral region RP, the first intermediate region R1 and the second intermediate region R2. The electrode portion 50E is provided in the element region RE. The pad portion 50P is provided in the pad portion region 10P. For example, the drain pad 52P is provided in a part of the pad portion region 10P. The source pad 51P and the gate pad 53P are provided in another part of the pad portion region 10P. At least a part of the first conductive member 61 and at least a part of the second conductive member 62 are provided in at least one of the first intermediate region R1 or the second intermediate region R2.

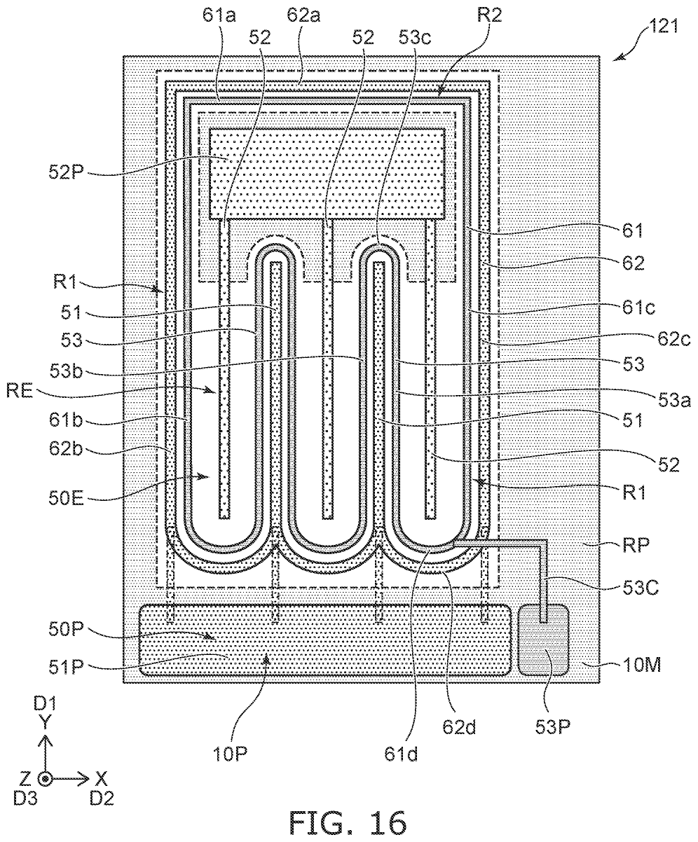

FIG. 16 is a schematic plan view illustrating the semiconductor device according to the second embodiment.

FIG. 16, some members are taken out and illustrated in order to make the figure easier to see.

As shown in FIG. 16, in a semiconductor device 121 according to the embodiment, the second conductive member 62 further includes the fourth conductive region 62d. Except for this, the configuration of the semiconductor device 121 may be the same as the configuration of the semiconductor device 120.

In the semiconductor device 121, the position of the fourth conductive portion 61d in the first direction D1 is between the position of the fourth conductive region 62d in the first direction D1 and the position of the drain electrode 52 in the first direction D1. For example, the electric field can be lowered in the region between the drain electrode 52 and the source pad 51P. For example, the leakage current can be suppressed.

For example, the fourth conductive region 62d may be continuous with the second conductive region 62b and the third conductive region 62c. For example, the drain electrode 52 is surrounded by at least one of the gate electrode 53 or the first conductive member 61. For example, the gate electrode 53 and the first conductive member 61 are surrounded by the second conductive member 62. For example, in a plan view, the drain pad 52P is surrounded by at least one of the gate electrode 53 or the first conductive member 61. The characteristics can be made more stable.

Hereinafter, an example of a method for manufacturing the semiconductor device according to the embodiment will be described. The following description corresponds to an example of a method for manufacturing the semiconductor device 121.

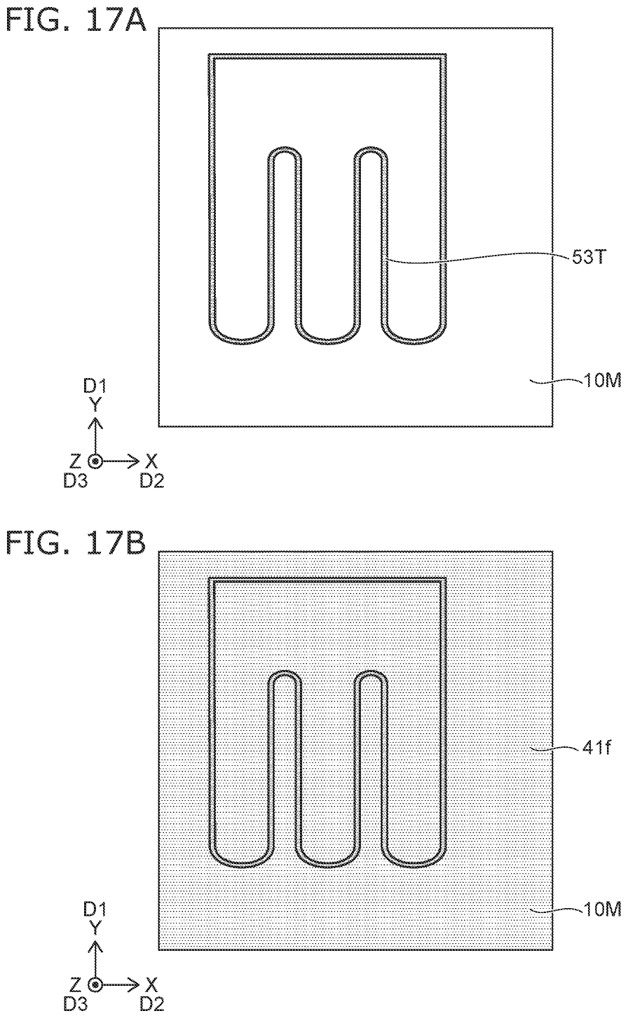

FIGS. 17A, 17B, 18A, 18B, 19A and 19B are schematic plan views illustrating the method for manufacturing the semiconductor device according to the embodiment.

As shown in FIG. 17A, a trench 53T is formed in the semiconductor member 10M. As will be described later, the gate electrode 53 and the first conductive member 61 are formed by forming a conductive layer in the trench 53T.

As shown in FIG. 17B, an insulating film 41f to be the first insulating member 41 is formed. At least a part of the insulating film 41f is provided in the trench 53T. After that, heat treatment (PDA: Post Deposition Annealing) may be performed. Prior to the formation of the insulating film 41f, the compound member 43 and the second insulating member 42 may be formed.

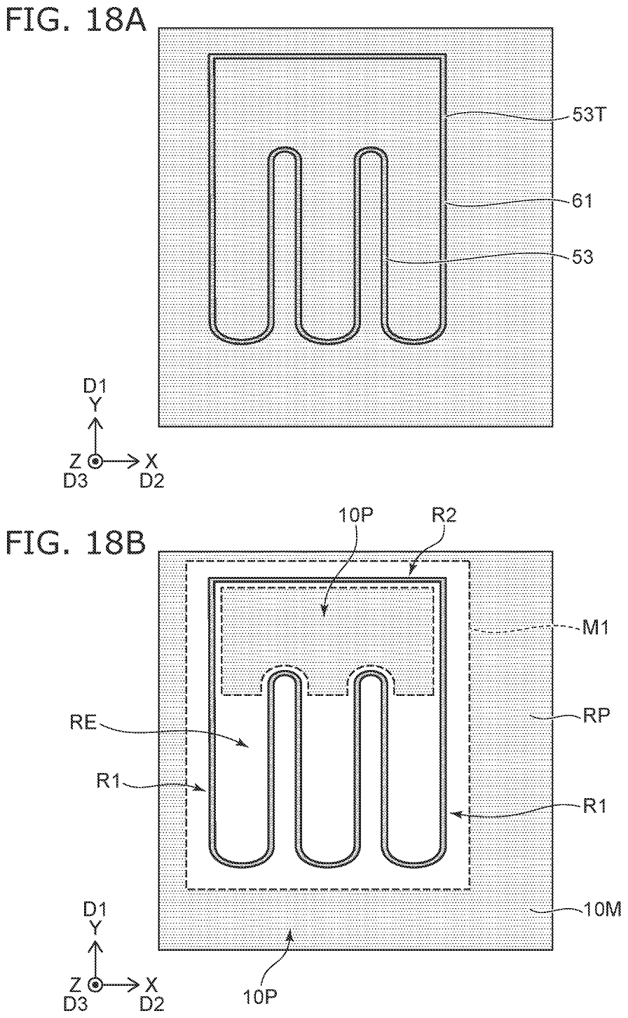

As shown in FIG. 18A, the gate electrode 53 and the first conductive member 61 are formed by embedding a conductive material in the trench 53T.

As shown in FIG. 18B, the first element is introduced into the semiconductor member 10M. The introduction is performed by, for example, ion implantation. By using a mask M1 in the introduction of the first element, a region in which the first element is introduced and a region in which the first element is not introduced are formed. The region into which the first element is introduced becomes the peripheral region RP and the pad portion region 10P. The region in which the first element is not introduced becomes the element region RE, the first intermediate region R1, and the second intermediate region R2.

For example, after the ion implantation process, a PDA for improving the quality of the first insulating member 41 may be performed. As a result, the crystallinity of the region into which the first element is introduced is restored, the element separation ability is deteriorated, and the leakage current is increased. For example, when the first insulating member 41 includes silicon oxide, a PDA at a high temperature is required. Leakage currents tend to deteriorate due to PDA at high temperatures.

Ion implantation is performed after the PDA, which reduces the leakage current. For example, the ion implantation is performed after the formation of the gate electrode 53 and the first conductive member 61. As a result, the first insulating member 41 provided in the trench 53T is less likely to be contaminated. For example, contamination from the mask material is unlikely to occur. For example, particles are unlikely to occur. Gate destruction due to contamination or particles is unlikely to occur. In the introduction of the first element, the gate electrode 53 and the first conductive member 61 are covered with the mask M1. Therefore, the equipment for introducing the first element is not contaminated with the materials included in the gate electrode 53 and the first conductive member 61. For example, when the gate electrode 53 does not surround the source electrode 51, the leakage current becomes large between the source electrode 51 and the drain electrode 52. By surrounding the source electrode 51 with the gate electrode 53, the leakage current can be reduced.

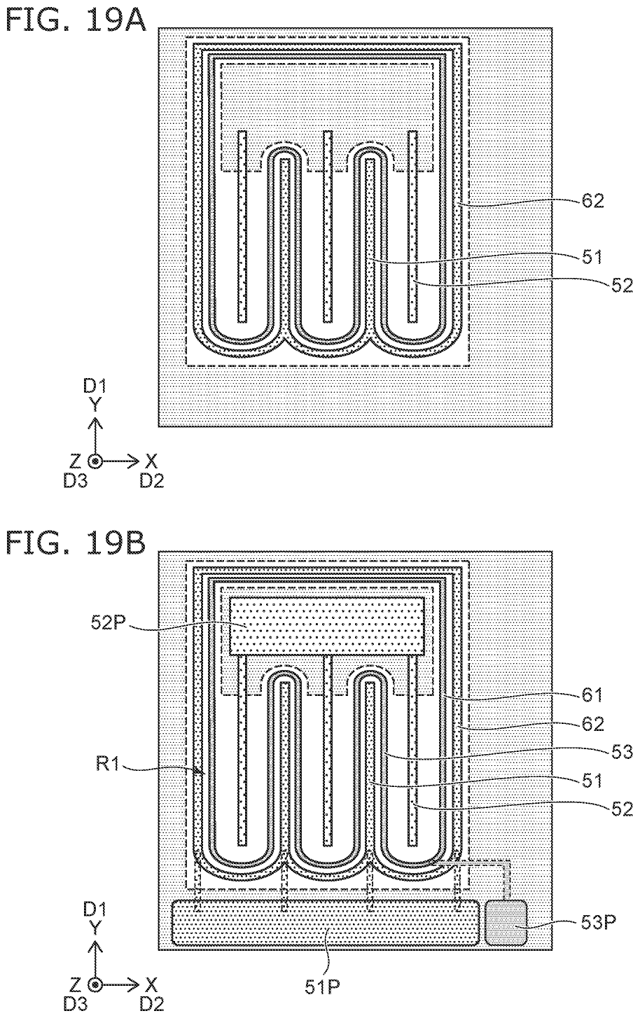

As shown in FIG. 19A, after removing the mask M1, the source electrode 51, the second conductive member 62, and the drain electrode 52 are formed. After this, the interlayer insulating portion 80 is formed.

As shown in FIG. 19B, the drain pad 52P, the source pad 51P, and the gate pad 53P are formed. If necessary, the insulating film 85 is formed. As a result, the semiconductor device 121 is formed.

Various semiconductor devices according to the embodiment can also be manufactured by appropriately modifying the above manufacturing method.

In the embodiment, the source electrode 51 includes, for example, at least one selected from the group consisting of Ti, Al and W. The drain electrode 52 includes, for example, at least one selected from the group consisting of Ti, Al and W. The gate electrode 53 includes, for example, at least one selected from the group consisting of TiN, WN, Ti, W, Ni, Pt, Au, Ta, TaN, Poly-Si, Poly-AlGaN, and Poly-GaN. The first conductive member 61 includes, for example, the same material as the material of the gate electrode 53. The second conductive member 62 includes, for example, the same material as the material of the source electrode 51.

Information on length, thickness and shape can be obtained by, for example, electron microscope observation. Information on the composition of the material can be obtained by, for example, SIMS (Secondary Ion Mass Spectrometry) or EDX (Energy dispersive X-ray spectroscopy).

According to the embodiment, it is possible to provide a semiconductor device capable of stabilizing the characteristics.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor devices such as semiconductor members, semiconductor layers, electrode portions, pad portions, conductive members, insulating members etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising
a semiconductor member including a first semiconductor layer including Alₓ₁Ga₁₋ₓ₁N (0≤x1<1) and a second semiconductor layer including Alₓ₂Ga₁₋ₓ₂N (0<x2≤1, x1<x2);
an electrode portion including
a source electrode extending along a first direction,
a gate electrode including a first gate portion extending along the first direction, and
a drain electrode extending along the first direction, the first gate portion being located between the source electrode and the drain electrode in a second direction crossing the first direction;
a pad portion including a drain pad electrically connected to the drain electrode;
a first conductive member electrically connected to the gate electrode, the first conductive member including a first conductive portion, a position of the drain pad in the first direction being between a position of the electrode portion in the first direction and a position of the first conductive portion in the first direction; and
a second conductive member electrically connected to the source electrode, the second conductive member including at least one of a first conductive region, a second conductive region, or a third conductive region,
a position of the first conductive portion in the first direction being between the position of the drain pad in the first direction and the position of the first conductive region in the first direction, a position of the electrode portion in the second direction being between a position of the second conductive region in the second direction and a position of the third conductive region in the second direction.

2. The device according to claim 1, wherein the second conductive region and the third conductive region are continuous with the first conductive region.

3. The device according to claim 1, wherein
the first conductive member further includes a second conductive portion and a third conductive portion,
a position of the second conductive portion in the second direction is between the position of the second conductive region in the second direction and the position of the electrode portion in the second direction, and
a position of the third conductive portion in the second direction is between the position of the electrode portion in the second direction and the position of the third conductive region in the second direction.

4. The device according to claim 3, wherein the second conductive portion and the third conductive portion are continuous with the first conductive portion.

5. The device according to claim 1, wherein
the pad portion further includes a source pad electrically connected to the source electrode, and
the position of the electrode portion in the first direction is between a position of the source pad in the first direction and the position of the drain pad in the first direction.

6. The device according to claim 1, wherein
the pad portion further includes a gate pad electrically connected to the gate electrode, and
the position of the electrode portion in the first direction is between a position of the gate pad in the first direction and the position of the drain pad in the first direction.

7. The device according to claim 1, wherein
the first conductive member further includes a fourth conductive portion,
the second conductive member further includes a fourth conductive region.
a position of the electrode portion in the first direction is between a position of the fourth conductive region in the first direction and the position of the drain pad in the first direction, and
a position of the fourth conductive portion in the first direction is between the position of the fourth conductive region in the first direction and the position of the electrode portion in the first direction.

8. The device according to claim 7, wherein
the fourth conductive portion is continuous with the first conductive portion, and
the fourth conductive region is continuous with the second conductive region and the third conductive region.

9. The device according to claim 1, further comprising a third conductive member electrically connected to the second conductive member, and
at least a part of the first conductive member being between the semiconductor member and the third conductive member in a third direction crossing a plane including the first direction and the second direction.

10. The device according to claim 5, further comprising:
a third conductive member electrically connected to the second conductive member; and
a second conductive member connecting portion electrically connecting the second conductive member to the source pad,
at least a part of the first conductive member being located between the semiconductor member and the third conductive member in a third direction crossing a plane including the first direction and the second direction, and
at least a part of the second conductive member connecting portion being between the third conductive member and the source pad in the first direction.

11. The device according to claim 6, further comprising a first conductive member connecting portion electrically connecting the first conductive member to the gate pad, and
a position of at least a part of the first conductive member connecting portion in a third direction crossing a plane including the first direction and the second direction being between a position of the first conductive member in the third direction and a position of the gate pad in third direction.

12. The device according to claim 1, wherein
the semiconductor member includes:
an element region;
a pad portion region; and
a peripheral region around the element region and the pad portion region in a plane including the first direction and the second direction,
the electrode portion is provided in the element region,
the pad portion is provided in the pad portion region, and
at least a part of the first conductive member and at least a part of the second conductive member are provided in at least one of the first intermediate region or the second intermediate region.

13. The device according to claim 12, wherein a crystallinity in the peripheral region and the pad portion region is lower than a crystallinity in the element region, the first intermediate region, and the second intermediate region.

14. The device according to claim 12, wherein
the gate electrode further includes a second gate portion, a third gate portion, and a fourth gate portion,
the second gate portion extends along the first direction,
in the second direction, the source electrode is located between the second gate portion and the drain electrode,
in the second direction, the source electrode is located between the second gate portion and the first gate portion, and
in the first direction, the source electrode is located between the third gate portion and the fourth gate portion.

15. The device according to claim 14, wherein the first gate portion, the second gate portion, the third gate portion, and the fourth gate portion are continuous with each other.

16. The device according to claim 1, wherein
the second conductive member includes the first conductive region, the second conductive region, and the third conductive region,
the second conductive region and the third conductive region are continuous with the first conductive region,
the first conductive member further includes a second conductive portion and a third conductive portion,
a position of the second conductive portion in the second direction is between the position of the second conductive region in the second direction and the position of the electrode portion in the second direction,
a position of the third conductive portion in the second direction is between the position of the electrode portion in the second direction and the position of the third conductive region in the second direction,
the second conductive portion and the third conductive portion are continuous with the first conductive portion,
the gate electrode further includes a second gate portion and a third gate portion,
the second gate portion extends along the first direction,
in the second direction, the source electrode is located between the second gate portion and the drain electrode,
in the second direction, the source electrode is located between the second gate portion and the first gate portion,
the second conductive portion is continuous with the second gate portion,
the third conductive portion is continuous with the first gate portion, and
a position of the third gate portion in the first direction is between a position of the source electrode in the first direction and a position of the drain pad in the first direction.

17. The device according to claim 16, wherein
the drain electrode is surrounded by at least one of the gate electrode or the first conductive member in a plane including the first direction and the second direction, and
the source electrode is provided outside a region surrounded by the at least one of the gate electrode or the first conductive member.

18. The device according to claim 16, wherein
the first conductive member further includes a fourth conductive portion, and
a position of the drain electrode in the first direction is between a position of the fourth conductive portion in the first direction and the position of the drain pad in the first direction.

19. The device according to claim 18, wherein
the second conductive member further includes a fourth conductive region, and
a position of the fourth conductive portion in the first direction is between a position of the fourth conductive region in the first direction and a position of the drain electrode in the first direction.

20. The device according to claim 1, wherein the first gate portion is located between a part of the second semiconductor layer and an other part of the second semiconductor layer in the second direction.
